(19) United States
(12) Patent Application Publication
(10) Pub. No.: US 2009/0313510 A1
(43) Pub. Date: Dec. 17, 2009

(54) PORT SELECTOR, DEVICE TESTING SYSTEM AND METHOD USING THE SAME

(75) Inventors: Hyun-chul KIM, Yongin-si (KR); Keun-Saeng KIM, Suwon (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon -si (KR)

(21) Appl. No.: 12/406,255

(22) Filed: Mar. 18, 2009

(30) Foreign Application Priority Data
Jun. 11, 2008 (KR) 2008-54766

(51) Int. Cl. G01R 31/28; G06F 13/00

(52) U.S. Cl. 714/712; 710/316; 714/E11.159

(57) ABSTRACT

A port selector, a device testing system and a method using the same. The port selector includes: a plurality of terminal ports to which a device is respectively coupled; an integration port which is connected to the plurality of terminal ports through a signal transmitting line; a plurality of terminal switches which are disposed to correspond to each terminal port, and open and close the signal transmitting line; and a control unit which independently controls each terminal switch. Thus, the present general inventive concept provides a port selector, a device testing system and a method using the same including a plurality of terminal ports to which devices are respectively coupled, and independently controlling each terminal port, thereby selecting a port.

### CROSS-REFERENCE TO RELATED APPLICATIONS

This application claims priority from Korean Patent Application No. 10-2008-0054766, filed on Jun. 11, 2008 in the Korean Intellectual Property Office, the disclosure of which is incorporated herein by reference in its entirety.

### BACKGROUND

1. Field of the Invention

The present general inventive concept relates to a port selector, a device testing system and a method using the same, and more particularly, to a port selector, a device testing system and a method using the same that independently control a plurality of terminal ports to select a port.

2. Description of the Related Art

In general, a display device such as a digital television, etc., includes a connecting port to which an external device is connected. For example, the display device includes a universal serial bus (hereinafter, referred to ‘USB’) port to which an external USB device is connected.

Here, it is necessary to test whether the USB device applied to the display device is appropriate for the display device before being supplied to a user.

In the conventional configuration, each external device to be tested is connected to the connecting port of the display device one to one, and then an appropriateness test is performed without a separate device testing system. In this case, since a required test time increases in proportion to the number of devices to be tested, the test time increases, and it is inconvenient that every device to be tested should be manually changed to perform the test.

Also, in the conventional configuration for connecting a plurality of USB devices, a USB hub having a plurality of ports to which each USB device is connected has been disclosed. If a device is tested by using this type of setup, since all USB devices connected to the plurality of ports are recognized, it is difficult to separately control the USB devices to be tested.

### SUMMARY

The general inventive concept provides a port selector, a device testing system and a method using the same including a plurality of terminal ports to which devices are respectively coupled, and independently controlling each terminal port, thereby selecting a port.

Additional aspects and utilities of the present general inventive concept will be set forth in part in the description which follows and, in part, will be obvious from the description, or may be learned by practice of the general inventive concept.

Embodiments of the present general inventive concept can be achieved by providing a port selector, comprising: a plurality of terminal ports to which a device is respectively coupled; an integration port which is connected to the plurality of terminal ports through a signal transmitting line; a plurality of terminal switches which are disposed to correspond to each terminal port, and open and close the signal transmitting line; and a control unit which independently controls each terminal switch.

The port selector may further comprise a control port which is connected to the control unit, and allows a control command to be inputted to the control unit or the inputted command to be changed through a coupled external control device.

The plurality of terminal ports and the plurality of terminal switches which correspond to each other can be classified into at least two terminal groups which respectively comprise a plurality of terminal ports and a plurality of terminal switches, and the port selector may further comprise a group switch which is disposed between the integration port and a plurality of terminal switches which belong to at least one terminal group, and is controlled by means of the control unit to open and close a signal transmitting line which connects at least one terminal group and the integration port.

At least one of the plurality of terminal switches and the group switch comprises a relay which physically opens or shorts the signal transmitting line.

The control port comprises a COM port.

The plurality of terminal ports and the integration port comprise at least one of a universal serial bus (USB) port, an IEEE 1394 port and a COM port.

Each terminal port may comprise a USB port, and a signal transmitting line which is connected to each terminal port comprises first to third signal transmitting lines which are respectively connected to a power supply terminal, a first data input/output terminal and a second data input/output terminal of the USB port.

The terminal switch independently opens and closes each of the first to third signal transmitting lines.

The second signal transmitting line and the third transmitting line are distanced from each other more than 0.2 mm.

The port selector may further comprise a capacitor which is connected in parallel with the first signal transmitting line to reduce a noise which flows into the power supply terminal of the USB port.

Embodiments of the present general inventive concept can also be achieved by providing a port selector, comprising: a plurality of terminal USB ports which are respectively coupled with a plurality of USB devices, and are classified into at least two terminal groups; an integration USB port which is connected to the plurality of terminal USB ports through a signal transmitting line; a plurality of terminal relays which are disposed to respectively correspond to the plurality of terminal USB ports, form the terminal groups together with the terminal USB ports having the corresponding position, and open and close the signal transmitting line; a group relay which is disposed between the integration USB port and a plurality of terminal relays which belong to at least one terminal group, and opens and closes a signal transmitting line which connects at least one terminal group and the integration USB port; a control unit which independently controls the plurality of terminal relays and the group relay; and a control port which is connected to the control unit, and allows a control command to be inputted to the control unit or the inputted command to be changed through a coupled external control device, the port selector selecting one of the plurality of terminal USB ports to connect to the integration USB port.

A signal transmitting line which is connected to each terminal port comprises first to third signal transmitting lines which are respectively connected to a power supply terminal, a first data input/output terminal and a second data input/output terminal of the terminal USB ports, and the second signal transmitting line and the third signal transmitting line are distanced from each other more than 0.2 mm, and the terminal relays and the group relay independently open and close each of the first to third signal transmitting lines.

Embodiments of the present general inventive concept can also be achieved by providing a device testing system to test a device which is applied to a display device, the device testing system comprising: a port selector which selects one of a plurality of terminal ports to which a device to be tested is respectively coupled to connect to an integration port; a display device which is connected to the integration port, and performs a test for the device which is coupled to the selected terminal port; a capture device which captures a test result which is received from the display device; and a control device which controls the selection of the terminal port, transmits a test command for the device to the display device, and stores a test result which is captured in the capture device, the device testing system evaluating whether the device to be tested is appropriate for the display device or not.

The port selector may comprise: a plurality of terminal ports to which a device is respectively coupled; an integration port which is connected to the plurality of terminal ports through a signal transmitting line; a plurality of terminal switches which are disposed to correspond to each terminal port, and open and close the signal transmitting line; a first control unit which independently controls each terminal switch; and a control port which connects the control device to the first control unit.

The plurality of terminal ports and the plurality of terminal switches which correspond to each other are classified into at least two terminal groups which respectively comprise a plurality of terminal ports and a plurality of terminal switches, and the device testing system may further comprise a group switch which is disposed between the integration port and a plurality of terminal switches which belong to at least one terminal group, and is controlled by means of the first control unit to open and close a signal transmitting line which connects at least one terminal group and the integration port.

At least one of the plurality of terminal switches and the group switch may comprise a relay which physically opens or shorts the signal transmitting line.

Each terminal port comprises a USB port, and a signal transmitting line which is connected to each terminal port comprises first to third signal transmitting lines which are respectively connected to a power supply terminal, a first data input/output terminal and a second data input/output terminal of the USB port.

The terminal switch can independently open and close each of the first to third signal transmitting lines.

The second signal transmitting line and the third transmitting line are distanced from each other more than 0.2 mm.

The display device may comprise a receiving unit which receives a test command from the control device; a first port which is connected the integration port, and transmits and receives a signal for the selected device to be tested; a display unit which displays a test image; a second port which outputs an image which is received from the device to be tested to the capture device; and a second control unit which controls the receiving unit, the first and second ports and display unit to perform a test which corresponding to the test command for the device to be tested.

The control device may comprise a third port which is connected to the control port, and inputs a control command to the first control unit; a transmitting unit which transmitting a test command to the receiving unit; a storing unit which stores a test result which is captured in the capture device; and a central processing unit which controls the third port, the transmitting unit and the storing unit.

Embodiments of the present general inventive concept can also be achieved by providing a device testing method to test a device which is applied to a display device, the device testing method comprising: (a) connecting one of at least one device to be tested to the display device; (b) transmitting a test command to the display device from a control device; (c) performing a test which corresponds to the transmitted test command for a device which is connected to the display device; (d) capturing a test result, and storing the captured test result; (e) determining whether all test item for the connected device is completed or not, and repeating the operations (b) to (d) if there remains a test item in the determination result; and (f) repeating the operations (a) to (e) if an other device to be tested is to be performed, if the test for the connected device is determined to be completed in the operation (e).

The operation (a) may comprise providing the port selector; coupling a device to be tested to at least one of the plurality of terminal ports; and selecting one of the plurality of terminal ports to which the device to be tested is coupled to connect to the integration port.

The operation (b) may comprise transmitting the test command from a transmitting unit of the control device to a receiving unit of the display device.

The device testing method may further comprise comparing the test result which is stored in the operation (d) with a reference value to evaluate whether the device to be tested is appropriate or not, and outputting the evaluating result.

Embodiments of the present general inventive concept can also be achieved by providing a device testing system, comprising: a plurality of terminal ports to each couple to a respective device; an integration port which is connected to the plurality of terminal ports through a signal transmitting line; and a control unit to independently control opening and closing of the signal transmission line to each terminal port through the integration port.

Embodiments of the present general inventive concept can also be achieved by providing a device testing method to test a device which is applied to a display device, the device testing method comprising: coupling to a plurality of devices to be tested via a signal transmission line; and independently controlling opening and closing a connection between each of the plurality of devices and the signal transmission line through a control unit to selectively test each of the plurality of devices.

### BRIEF DESCRIPTION OF THE DRAWINGS

These and/or other features and utilities of the present general inventive concept will become apparent and more readily appreciated from the following description of the exemplary embodiments, taken in conjunction with the accompanying drawings, in which:

FIG. 1 is a block diagram illustrating a port selector according to an exemplary embodiment of the present general inventive concept;

FIG. 2 illustrates a disposition configuration between the port selector and a switch according to the exemplary embodiment of FIG. 1;

FIG. 3 is a block diagram illustrating a port selector according to another exemplary embodiment of the present general inventive concept;

FIG. 4 is a circuit diagram according to an exemplary embodiment of a terminal switch and a group switch of the port selector in FIG. 3;

FIG. 5 is a circuit diagram according to an exemplary embodiment of a terminal port and a control switch of the port selector in FIG. 3;

FIG. 6 is a block diagram illustrating a device testing system according to an exemplary embodiment of the present general inventive concept; and

FIG. 7 is a flowchart illustrating a device testing method according to an exemplary embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to like elements throughout. The exemplary embodiments are described below so as to explain the present general inventive concept by referring to the figures.

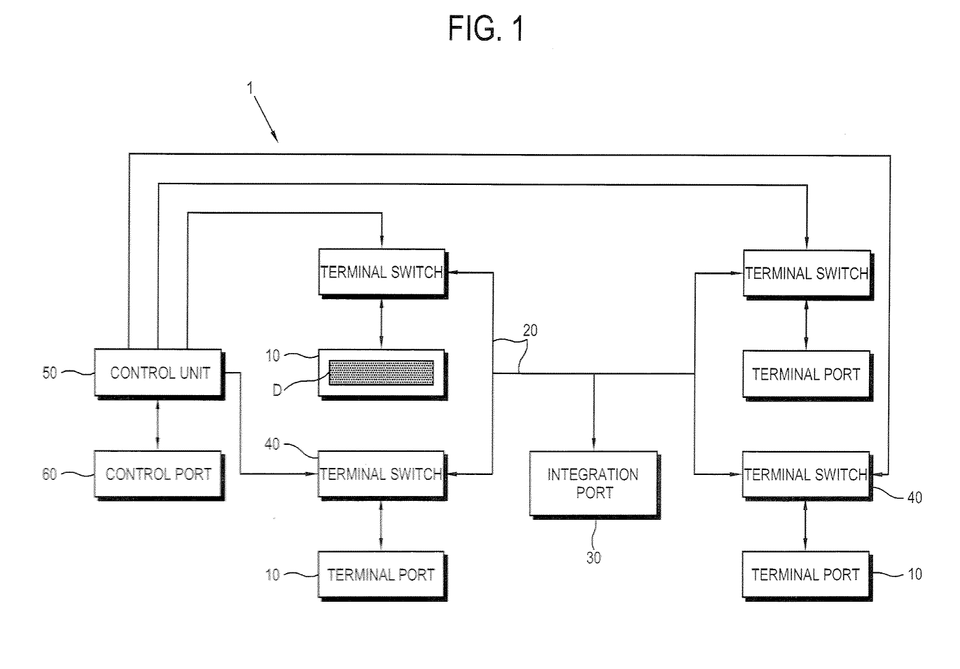

FIG. 1 is a block diagram illustrating a port selector according to an exemplary embodiment of the present general inventive concept.

As shown therein, a port selector 1 according to present exemplary embodiment includes a plurality of terminal ports 10, an integration port 30 connected to the plurality of terminal ports 10 through a signal transmitting line 20, a plurality of terminal switches 40 disposed to correspond to each terminal port 10 and to open and close the signal transmitting line 20, and a control unit 50 to control the plurality of terminal switches 40. The control unit 50 independently controls each terminal switch 40 to allow the terminal port 10 selected among the plurality of terminal ports 10 to be connected to the integration port 30.

Each terminal port 10 is coupled with an external device D such as a universal serial bus (USB) memory, etc. Here, the external device D may be directly coupled to the terminal port 10, or may be connected to the terminal port 10 through a separate connecting cable.

The plurality of terminal ports 10 and the integration port 30 may be implemented as various ports such as a USB port, an IEEE 1394 port, a COM port, a PS/2 port, etc. to be applied to the external device having various port configurations.

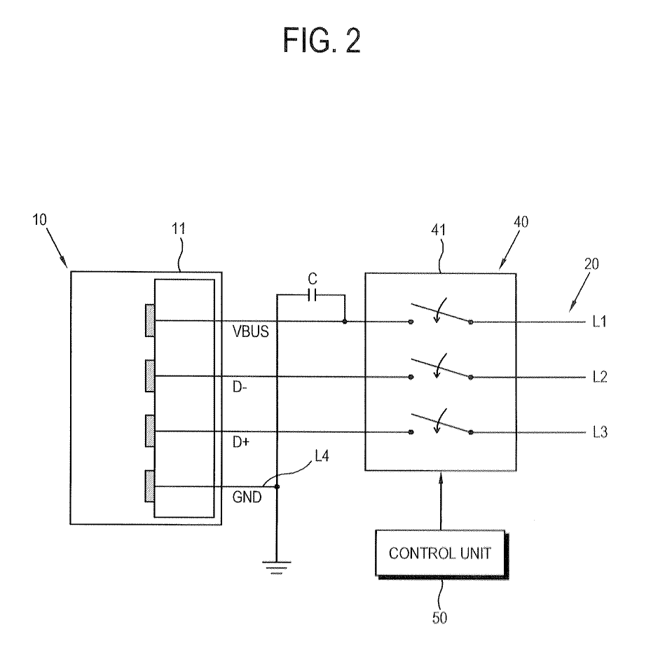

For example, as shown in FIG. 2, each terminal port 10 may be implemented as a USB port 11.

As shown in FIG. 2, the USB port 11 has a four-terminal configuration, and includes a power supply terminal VBUS, a first data input/output terminal D−, a second data input/output terminal D+ and a ground terminal GND. In this case, the signal transmitting line 20 connected to each terminal port 10 includes a plurality of transmitting lines. That is, the signal transmitting line 20 includes first to fourth signal transmitting lines L1, L2, L3 and L4 respectively connected to the power supply terminal VBUS, the first data input/output terminal D−, the second data input/output terminal D+ and the ground terminal GND of the USB port 11.

Here, in configuring the signal transmitting line 20, if an interval between the second signal transmitting line L2 and the third signal transmitting line L3 is under 0.2 mm, a cross talk such as a signal leakage, etc., may be generated due to an effect as if there is formed a capacitor between the two lines, that is, a capacitor effect defined as ‘stray capacitance’. To prevent this, the second signal transmitting line L2 and the third signal transmitting line L3 are preferably, but not necessarily, distanced from each other by more than 0.2 mm. Accordingly, a signal interference among data signals transmitted through the second and third signal transmitting lines L2 and L3 may be reduced.

Also, the present general inventive concept may further include a capacitor C connected to the first signal transmitting lines L1. The capacitor C is connected in parallel between the power supply terminal VBUS and the ground terminal GND, and reduces noises flowing into the power supply terminal VBUS of the USB port 11.

The terminal switch 40 is driven by means of the control unit 50, and independently opens and closes the first to third signal transmitting lines L1, L2 and L3. For this, each terminal switch 40 may include a relay 41 to physically open or short the signal transmitting line 20.

Like this, by employing the relay 41 to physically open and close the signal transmitting line 20, when selecting the terminal port 10 and connecting to the integration port 30, a signal deterioration due to the signal transmitting line 20 not contributing to the connection may be prevented.

Also, the present general inventive concept may further include a control port 60. The control port 60 is connected to the control unit 50, and is coupled to an external control device. The control port 60 may be implemented as a COM port, which is a type of a serial port. Accordingly, through the control port 60, a control command may be input to the control unit 50 from the external control device or the command input to the control unit 50 may be changed.

As describe above, the port selector 1 according to the exemplary embodiment of FIG. 1 opens and closes the terminal switch 40 by using the control unit 50, thereby selecting one terminal port among the plurality of terminal ports 10 and connecting to the integration port 30.

Accordingly, if an external device to be tested is in plural, each external device is connected to a respective one of the terminal ports 10, and then the terminal port 10 to which each external device is connected is automatically selected to be connected to a testing device, thereby improving a testing convenience.

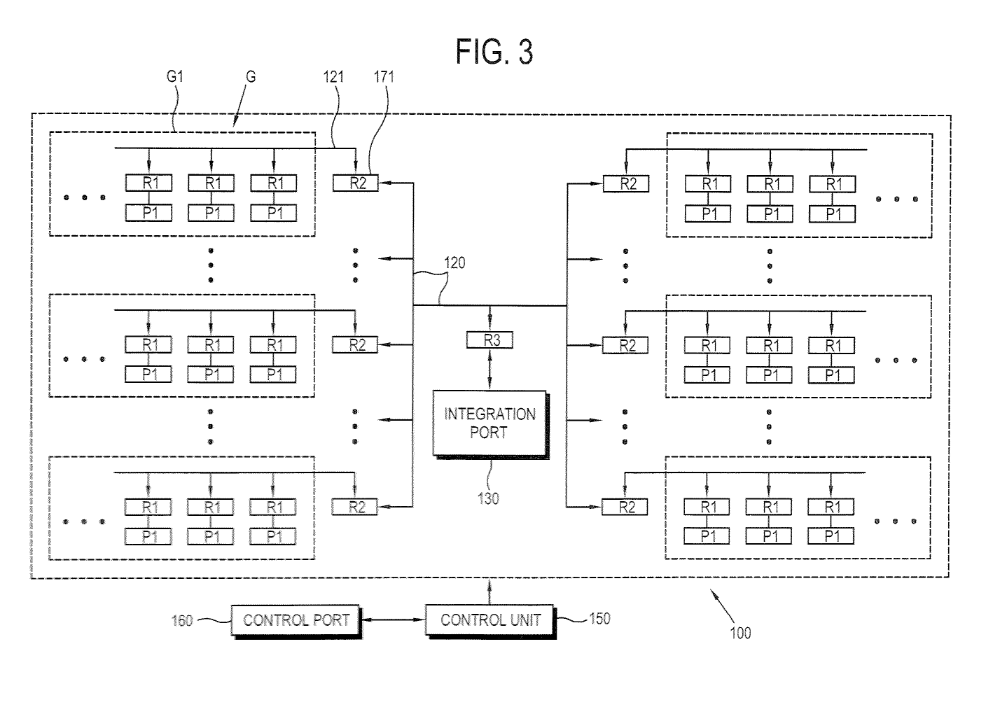

FIG. 3 is a schematic block diagram illustrating a port selector according to another exemplary embodiment of the present general inventive concept.

If the port selector 1 is configured as shown in FIG. 1, when the number of terminal ports 10 increases, it is difficult to perform a normal testing for the device D connected to the terminal port 10 relatively distanced from the integration port 30 due to a signal loss in the signal transmitting lines. With a consideration of this, as shown in FIG. 3, a port selector 100 according to the present exemplary embodiment includes a group switch R2 on a signal transmitting line.

As shown in FIG. 3, the port selector 100 according to the present exemplary embodiment includes a plurality of terminal ports P1, an integration port 130, a plurality of terminal switches R1, a group switch R2 and a control unit 150. The control unit 150 controls each terminal switch R1 and the respective group switch R2 so that the terminal port selected among the plurality of terminal ports P1 can be connected to the integration port 130. Also, the exemplary embodiment may further include a control port 160 to connect the control unit 150 to an external control device.

Here, the plurality of terminal ports P1 and the plurality of terminal switches R1 corresponding to each other are classified into at least two terminal groups G. Each terminal group includes a plurality of terminal ports P1 and a plurality of terminal switches R1 respectively corresponding thereto.

The group switches R2 are disposed between the integration port 130 and the respective plurality of terminal switches R1 belonging to at least one terminal group G. The group switch R2 is controlled by the control unit 150 to open and close a signal transmitting line 120 connecting at least one terminal group G and the integration port 130.

In more detail, as shown in FIG. 3, the group switch R2 is disposed to represent each terminal group G. Accordingly, if one terminal port among the plurality of terminal ports P1 belonging to a first terminal group G1 is connected to the integration port 130, the control unit 150 makes only the first group switch 171 among the plurality of group switches R2 be closed to form an electric path 121 between the first terminal group G1 and the integration port 130. At this time, the remaining group switches except the first group switch 171 are physically opened. Accordingly, since the signal transmitting lines between the group switches R2 and the terminal switches R1 except the electric path 121 are not applied with a signal, a signal interference due to a signal line physically opened may be prevented. Also, the control unit 150 causes the terminal switch corresponding to the terminal port which is to be connected to be closed, thereby forming an electronic path between the terminal port to be connected and the integration port 130.

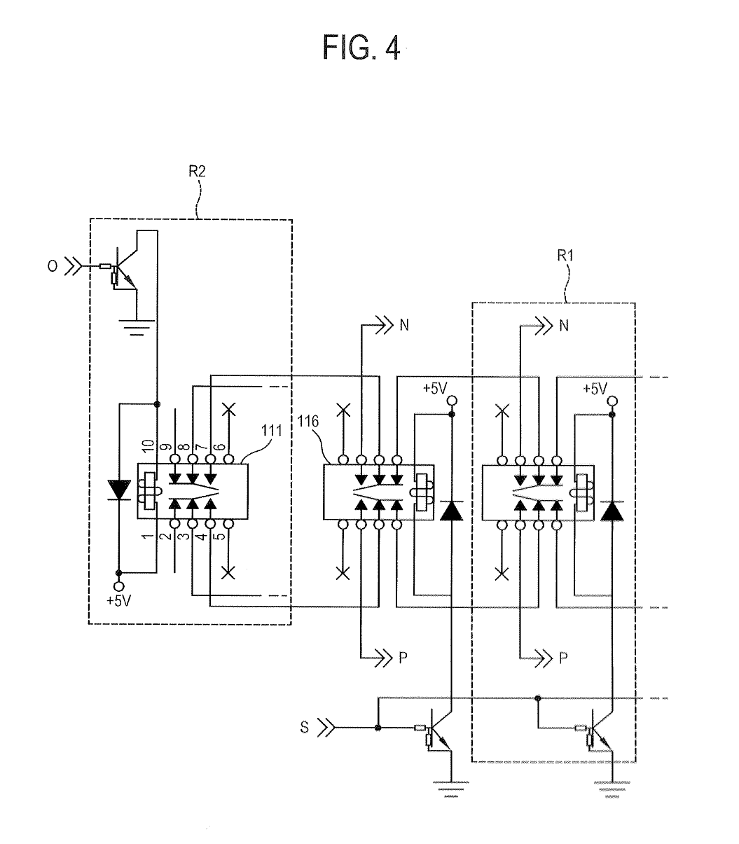

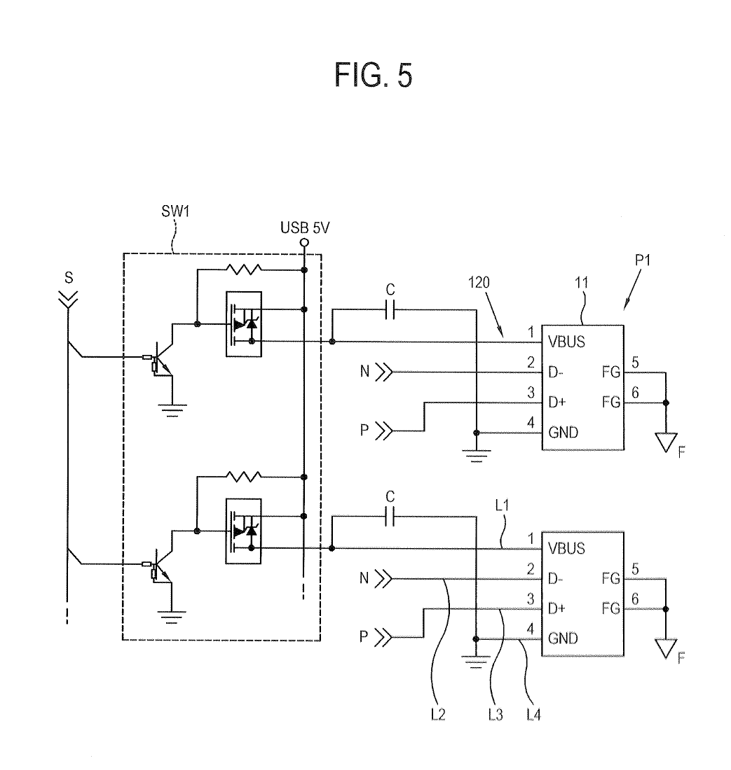

Here, the terminal switch R1 and the group switch R2 are driven by means of the control unit 150, and as shown in FIGS. 4 and 5, may include a relay to physically open and close the signal transmitting line 120.

FIG. 4 is a circuit diagram according to an exemplary embodiment of the terminal switch R1 and the group switch R2. FIG. 5 is a circuit diagram illustrating the terminal port and the control switch SW1.

As shown in FIG. 4, the group switch R2 may include a first relay 111 driven depending on a switching signal O input from the control unit 150 in FIG. 3, a transistor and a diode. Here, the transistor and the diode allow the first relay 111 to drive depending on whether the switching signal O is applied. Here, as the first relay 111 composing the group switch R2, a relay provided with ten terminals is exemplarily illustrated.

The terminal switch R1 may include a second relay 116 driven depending on a switching signal S input from the control unit 150 in FIG. 3, a transistor and a diode. FIG. 4 exemplarily illustrates a relay provided with ten terminals as the second relay 116 composing the terminal switch R1. Here, since some terminals (terminals 7 and 4) of the first relay 111 are connected to some terminals (terminals 3 and 8) of the second relay 116, when the first relay 111 is switched off, the second relay 116 is prevented from operating although the switching signal S is input. That is, the second relay 116 is driven depending on the switching signal S under a precondition that the first relay 111 is switched on.

Also, signals N and P respectively output from terminals 4 and 7 of the second relay 116 are transmitted to the signal transmitting line of the terminal port.

As shown in FIG. 5, each terminal port P1 may be implemented as a USB port 11. The USB port 11 has a configuration having four terminals, and includes a power supply terminal VBUS, a first data input/output terminal D−, a second data input/output terminal D+ and a ground terminal GND. In this case, the signal transmitting line 120 connected to each terminal port P1 includes a plurality of transmitting lines. That is, the signal transmitting line 120 includes first to fourth signal transmitting lines L1, L2, L3 and L4 respectively connected to the power supply terminal VBUS, the first data input/output terminal D−, the second data input/output terminal D+ and the ground terminal GND. Also, the present general inventive concept may further include a capacitor C connected to the first signal transmitting line L1. Here, the function of the capacitor C and the interval between the second signal transmitting line L2 and the third signal transmitting line L3 may be substantially the same as the terminal port 10 in the embodiment of FIG. 1.

The signals N and P respectively output from the terminals 4 and 7 of the second relay 116 in FIG. 4 are respectively input to the first data input/output terminal D− and the second data input/output terminal D+ through the second and third signal transmitting lines L2 and L3.

Also, the first signal transmitting line L1 is selectively applied with a USB power supply (for example, direct current 5V) depending on an on/off control of the control switch SW1. The control switch SW1 operates depending on the switching signal S input from the control unit 150 in FIG. 3, and is exemplarily illustrated to include a transistor, a resistance and a metal oxide semiconductor field effect transistor (MOSFET) in FIG. 5. Here, the control switch SW1 is a part of the terminal switch R1, and is not illustrated in FIGS. 1 to 3 for a convenience.

Also, the present general inventive concept may further include an integration switch R3 opening the total signal transmitting line 120 and disposed between the signal transmitting line 120 and the integration port 130. In this case, the integration switch R3 may be implemented as a relay, and performs an opening and closing operation under a control command from the control unit 150.

As described above, by including the group switch R2 and controlling the group switch R2 to secure the electronic path physically having a minimum length, a signal loss in the signal transmitting line may be reduced when performing a testing for a device connected to a terminal port relatively distanced from the integration port 130.

Here, the configurations of the terminal port P1, the integration port 130, the signal transmitting line 120, the terminal switch R1 and the control unit 150 may have the substantially same as the port selector 1 according to the exemplary embodiment of FIG. 1.

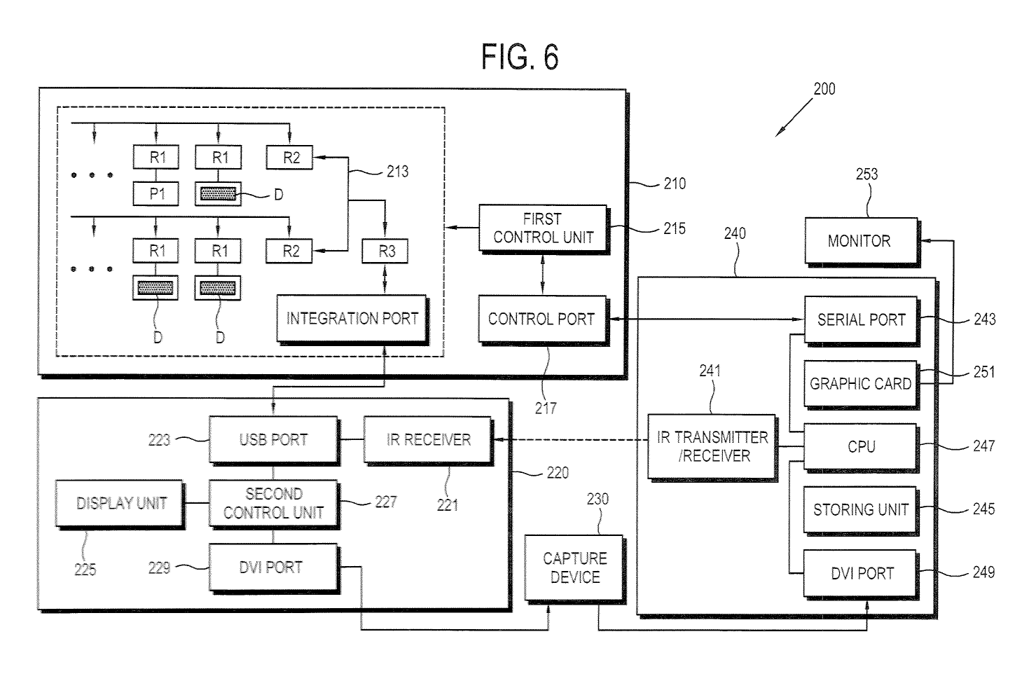

FIG. 6 is a block diagram illustrating a device testing system according to an exemplary embodiment of the present general inventive concept. As shown therein, a device testing system 200 according to this exemplary embodiment can test whether a test target device D is appropriate for a display device 220, and includes a port selector 210, the display device 220, a capture device 230 and a control device 240.

The port selector 210 selects one terminal port among a plurality of terminal ports P1 to which the test target devices D are coupled to connect to an integration port 211. For this, the port selector 210 includes a plurality of terminal ports P1, the integration port 211 connected to the plurality of terminal ports P1 through a signal transmitting line 213, a plurality of terminal switches R1, a first control unit 215 independently controlling each terminal switch R1, and a control port 217. Also, the port selector 210 may further include a group switch R2 and an integration switch R3.

The port selector 210 corresponds to the port selectors 1 and 100 according to the exemplary embodiments described above by referring to FIGS. 1 to 5, and a detailed description thereof is therefore omitted for the convenience of description. The first control unit 215 corresponds to the control units 50 and 150 in FIGS. 1 and 3.

The display device 220 is connected to the integration port 211, and performs a test for the device D connected to the terminal port P1 selected. Here, the selection of the terminal port P1 is performed in the first control unit 215. That is, if three devices D are mounted to the port selector 210, the first control unit 215 selectively connects the terminal port to which the three devices D are connected to the integration port 211. Also, the display device 220 performs a test for the device D connected to the integration port 211 depending on a testing command received from the control device 240.

For this, the display device 220 includes a receiving unit (i.e., IR Receiver) 221, a first port (i.e., USB Port) 223, a display unit 225 in which a testing image is displayed, a second control unit 227 and a second port 229. The receiving unit 221 receives the testing command from a transmitting unit (i.e., IR Transmitter/Receiver) 241 of the control device 240. Here, the transmitting unit 241 and the receiving unit 221 may transmit and receive the test command by means of a wireless communication using an infrared ray. For this, the transmitting unit 241 and the receiving unit 221 may be respectively implemented as an infrared ray transmitter and an infrared ray receiver.

The first port 223 can be implemented as a USB port, etc., and is connected to the integration port 211. The first port 223 transmits and receives a signal for the selected test target device. Accordingly, the same effect as the test target device D coupled to the port selector 210 is directly connected to the first port 223 may be obtained.

The second port 229 may include a DVI port, etc., and outputs an image received from the test target device D to the capture device 230.

The second control unit 227 controls the receiving unit 221, the first and second ports 223 and 229 and the display unit 225 to perform a test corresponding to the test command for the test target device.

The capture device 230 is connected to the display device 220 through the second port 229, and captures a test result received from the display device 220. Also, the capture device 230 supplies a captured image to the control device 240. For this, the capture device 230 may be implemented as an LDVS-DVI inverter, and is connected to the second port 229 and a DVI port 249 of the control device 240 through a DVI cable.

The control device 240 controls selection of the terminal port P1, transmits the test command for the device D to the display device 220, and stores a test result captured in the capture device 230. For this, the control device 240 includes a third port (i.e., Serial Port) 243 connected to the control port 217 to input a control command to the first control unit 215 and implemented as a serial port, etc., the transmitting unit 241 to transmit the test command to the receiving unit 221, a storing unit 245 to store the test result captured in the capture device 230, and a central processing unit (CPU) 247 to control all of these units. The CPU 247 controls the first control unit 215 through the third port 243, controls the transmitting unit 241 to transmit the test command for the device D to the display device 220, and stores the test result received in the capture device 230 in the storing unit 245.

Also, the control device 240 may include a graphic card 251 and a monitor 253 to monitor the test result stored in the storing unit 245. In this case, the CPU 247 may determine deterioration of the test target device based on the test result stored in the storing unit 245, and may make the determination result displayed in the monitor 253.

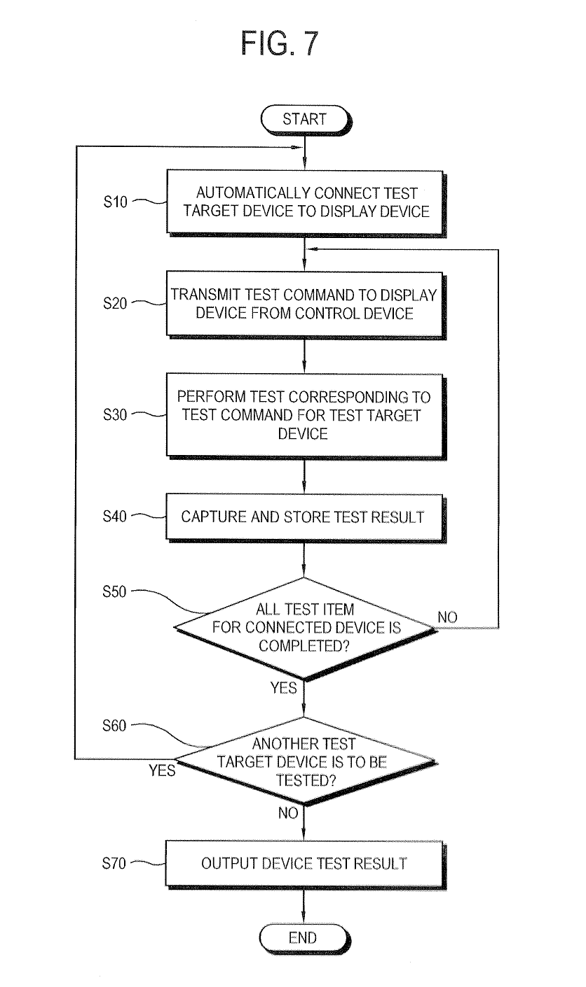

FIG. 7 is a flowchart illustrating a device testing method according to an exemplary embodiment. As shown in FIGS. 1 to 7, the device testing method according to the present exemplary embodiment includes the following operations S10 to S60.

At first, at least one test target device is connected to the display device 220 (operation S10). The operation S10 includes providing one of the port selectors 1 and 100 according to the exemplary embodiments described by referring to FIGS. 1 to 3, coupling a test target device D to at least one of the plurality of terminal ports P1, and selecting one of the plurality of terminal ports P1 to which the test target device D is coupled to connect to the integration port 130 in FIG. 3. Here, the connecting of the test target device D to the integration port 130 is performed automatically by means of the control unit 150 in FIG. 3.

Then, the control device 240 transmits a test command to the display device 220 (operation S20). The operation S20 includes transmitting the test command from the transmitting unit 241 of the control device 240 to the receiving unit 221 of the display device 220. The test command includes one of a command corresponding to whether each terminal of the device D normally operates or not, and an executing command of each test information.

Then, a test corresponding to the test command transmitted from the control device 240 is performed for the device D connected to the display device 220 (S30). Here, to perform the operation S30, a test information, for example, information such as a motion picture, music, photograph, etc. is included in the device D. Here, a test result is transmitted to the capture device 230 through the second port 229 in FIG. 6.

The capture device 230 captures the test result in the operation S30, and transmits the captured test result to the control device 240. The CPU 247 stores the transmitted captured result in the storing unit 245 (S40).

Then, it is determined whether all items of the test for the selected device D are completed or not, and the operations S20 to S40 are repeated if there remains a test item in the determination result (S50).

If the test for the connected device D is determined to be completed in the operation S50, the operations S10 to S50 are repeated if a test for another test target device is to be performed (S60).

The present general inventive concept can also be embodied as computer-readable codes on a computer-readable medium. The computer-readable medium can include a computer-readable recording medium and a computer-readable transmission medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network coupled computer systems so that the computer-readable code is stored and executed in a distributed fashion. The computer-readable transmission medium can transmit carrier waves or signals (e.g., wired or wireless data transmission through the Internet). Also, functional programs, codes, and code segments to accomplish the present general inventive concept can be easily construed by programmers skilled in the art to which the present general inventive concept pertains.

Also, the device testing method according to the present general inventive concept may further include comparing the test result stored through the operation S40 with a reference value to evaluate whether the test target device D is appropriate or not, and outputting this (S70).

A port selector according to embodiments of the present general inventive concept includes a plurality of terminal ports to which a device is coupled, and independently controls the terminal ports, thereby automatically selecting a port. Accordingly, a plurality of devices connected to the terminal ports may be selectively connected to an integration port. Also, in configuring the port selector, by employing a group switch, a signal noise may be reduced when the device is connected to the terminal port relatively distanced from the integration port.

Also, device testing system and method according to embodiments of the present general inventive concept uses the above port selector, automatically selects each test target device to connect to a display device, and tests, thereby automating a test. Accordingly, time necessary for the test may be reduced, and a test inferiority may be reduced.

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents.

What is claimed is:

1. A port selector, comprising:
a plurality of terminal ports to which a device is respectively coupled;
an integration port which is connected to the plurality of terminal ports through a signal transmitting line;
a plurality of terminal switches which are disposed to correspond to each terminal port, and open and close the signal transmitting line; and
a control unit which independently controls each terminal switch.

2. The port selector according to claim 1, further comprising:
a control port which is connected to the control unit, and allows a control command to be inputted to the control unit or the inputted command to be changed through a coupled external control device.

3. The port selector according to claim 2, wherein the plurality of terminal ports and the plurality of terminal switches which correspond to each other are classified into at least two terminal groups which respectively comprise the plurality of terminal ports and the plurality of terminal switches, and
the port selector further comprises a group switch which is disposed between the integration port and the plurality of terminal switches which belong to at least one terminal group, and is controlled by means of the control unit to open and close the signal transmitting line which connects at least one terminal group and the integration port.

4. The port selector according to claim 3, wherein at least one of the plurality of terminal switches and the group switch comprises a relay which physically opens or shorts the signal transmitting line.

5. The port selector according to claim 2, wherein the control port comprises a COM port.

6. The port selector according to claim 1, wherein the plurality of terminal ports and the integration port comprise at least one of a universal serial bus (USB) port, an IEEE 1394 port and a COM port.

7. The port selector according to claim 1, wherein each terminal port comprises a USB port, and the signal transmitting line comprises first to third signal transmitting lines which are respectively connected to a power supply terminal, a first data input/output terminal and a second data input/output terminal of the USB port.

8. The port selector according to claim 7, wherein the terminal switch independently opens and closes each of the first to third signal transmitting lines.

9. The port selector according to claim 8, wherein the second signal transmitting line and the third transmitting line are distanced from each other more than 0.2 mm.

10. The port selector according to claim 9, further comprising a capacitor which is connected in parallel with the first signal transmitting line to reduce a noise which flows into the power supply terminal of the USB port.

11. A port selector, comprising:
a plurality of terminal USB ports which are respectively coupled with a plurality of USB devices, and are classified into at least two terminal groups;
an integration USB port which is connected to the plurality of terminal USB ports through a signal transmitting line;
a plurality of terminal relays which are disposed to respectively correspond to the plurality of terminal USB ports, form the terminal groups together with the terminal USB ports having the corresponding position, and open and close the signal transmitting line;
a group relay which is disposed between the integration USB port and the plurality of terminal relays which belong to at least one terminal group, and opens and closes the signal transmitting line which connects at least one terminal group and the integration USB port;
a control unit which independently controls the plurality of terminal relays and the group relay; and
a control port which is connected to the control unit, and allows a control command to be inputted to the control unit or the inputted command to be changed through a coupled external control device,
the port selector selecting one of the plurality of terminal USB ports to connect to the integration USB port.

12. The port selector according to claim 11, wherein the signal transmitting line comprises first to third signal transmitting lines which are respectively connected to a power supply terminal, a first data input/output terminal and a second data input/output terminal of the terminal USB ports, and the second signal transmitting line and the third signal transmitting line are distanced from each other more than 0.2 mm, and
the terminal relays and the group relay independently open and close each of the first to third signal transmitting lines.

13. A device testing system to test a device which is applied to a display device, the device testing system comprising:
a port selector which selects one of a plurality of terminal ports to which a device to be tested is respectively coupled to connect to an integration port;
a display device which is connected to the integration port, and performs a test for the device which is coupled to the selected terminal port;
a capture device which captures a test result which is received from the display device; and
a control device which controls the selection of the terminal port, transmits a test command for the device to the display device, and stores the test result which is captured in the capture device,
the device testing system evaluating whether the device to be tested is appropriate for the display device.

14. The device testing system according to claim 13, wherein the port selector comprises:
a plurality of terminal ports to which a device is respectively coupled;
an integration port which is connected to the plurality of terminal ports through a signal transmitting line;
a plurality of terminal switches which are disposed to correspond to each terminal port, and open and close the signal transmitting line;
a first control unit which independently controls each terminal switch; and
a control port which connects the control device to the first control unit.

15. The device testing system according to claim 14, wherein the plurality of terminal ports and the plurality of terminal switches which correspond to each other are classified into at least two terminal groups which respectively comprise the plurality of terminal ports and the plurality of terminal switches, and
the device testing system further comprises a group switch which is disposed between the integration port and the plurality of terminal switches which belong to at least one terminal group, and is controlled by means of the first control unit to open and close the signal transmitting line which connects at least one terminal group and the integration port.

16. The device testing system according to claim 15, wherein at least one of the plurality of terminal switches and the group switch comprises a relay which physically opens or shorts the signal transmitting line.

17. The device testing system according to claim 16, wherein each terminal port comprises a USB port, and
the signal transmitting line which is connected to each terminal port comprises first to third signal transmitting lines which are respectively connected to a power supply terminal, a first data input/output terminal and a second data input/output terminal of the USB port.

18. The device testing system according to claim 17, wherein the terminal switch independently opens and closes each of the first to third signal transmitting lines.

19. The device testing system according to claim 18, wherein the second signal transmitting line and the third transmitting line are distanced from each other more than 0.2 mm.

20. The device testing system according to claim 14, wherein the display device comprises:
a receiving unit which receives a test command from the control device;
a first port which is connected the integration port, and transmits and receives a signal for the selected device to be tested;
a display unit which displays a test image;
a second port which outputs an image which is received from the device to be tested to the capture device; and
a second control unit which controls the receiving unit, the first and second ports and display unit to perform a test which corresponding to the test command for the device to be tested.

21. The device testing system according to claim 20, wherein the control device comprises:
a third port which is connected to the control port, and inputs a control command to the first control unit;
a transmitting unit which transmitting a test command to the receiving unit;
a storing unit which stores a test result which is captured in the capture device; and
a central processing unit which controls the third port, the transmitting unit and the storing unit.

22. A device testing method to test a device which is applied to a display device, the device testing method comprising:
(a) connecting one of at least one device to be tested to the display device;
(b) transmitting a test command to the display device from a control device;
(c) performing a test which corresponds to the transmitted test command for a device which is connected to the display device;
(d) capturing a test result, and storing the captured test result;
(e) determining whether all test items for the connected device is completed, and repeating the operations (b) to (d) if there remains a test item in the determination result; and
(f) repeating the operations (a) to (e) if an other device to be tested is to be performed, if the test for the connected device is determined to be completed in the operation (e).

23. The device testing method according to claim 22, wherein the operation (a) comprises:
providing the port selector according to claim 2;
coupling a device to be tested to at least one of the plurality of terminal ports; and
selecting one of the plurality of terminal ports to which the device to be tested is coupled to connect to the integration port.

24. The device testing method according to claim 23, wherein the operation (b) comprises transmitting the test command from a transmitting unit of the control device to a receiving unit of the display device.

25. The device testing method according to claim 22, further comprising:
comparing the test result which is stored in the operation (d) with a reference value to evaluate whether the device to be tested is appropriate, and outputting the evaluating result.

26. A computer readable recording medium containing readable codes that perform a device testing method to test a device which is applied to a display device, the device testing method comprising:
(a) connecting one of at least one device to be tested to the display device;
(b) transmitting a test command to the display device from a control device;
(c) performing a test which corresponds to the transmitted test command for a device which is connected to the display device;
(d) capturing a test result, and storing the captured test result;
(e) determining whether all test items for the connected device is completed, and repeating the operations (b) to (d) if there remains a test item in the determination result; and
(f) repeating the operations (a) to (e) if an other device to be tested is to be performed, if the test for the connected device is determined to be completed in the operation (e).
